(19) United States
(12) Patent Application Publication
(10) Pub. No.: US 2008/0044984 A1
(43) Pub. Date: Feb. 21, 2008

(54) METHODS OF AVOIDING WAFER BREAKAGE DURING MANUFACTURE OF BACKSIDE ILLUMINATED IMAGE SENSORS

(75) Inventors: Yuan-Chih Hsieh, Hsinchu City (TW); Chung-Yi Yu, Hsin-Chu (TW); Gwo-Yuh Shiau, Hsinchu City (TW); Shih-Chi Fu, Taipei City (TW); Ming Chyi Liu, Hsinchu City (TW); Chia-Shiung Tsai, Hsin-Chu (TW)

Correspondence Address: DUANE MORRIS LLP;IP DEPARTMENT (TSMC), 30 SOUTH 17TH STREET, PHILADELPHIA, PA, 19103-4196, US

(73) Assignee: TAIWAN SEMICONDUCTOR MANUFACTURING CO., LTD., Hsinchu City (TW)

(21) Appl. No.: 11/465,047

(22) Filed: Aug. 16, 2006

(51) Int. Cl. H01L 21/30; H01L 21/46

(52) U.S. Cl. 438/459

(57) ABSTRACT

A process for forming backside illuminated devices is disclosed. Specifically, the process reduces processing damage to wafers caused by poor bond quality at the wafer edge ring. In one embodiment, a wafer edge trimming step is implemented prior to bonding the wafer to the substrate. A pre-grind blade is used to create a straight edge around the wafer perimeter, eliminating any sharp edges. In another embodiment, edge trimming is performed after the wafer has been bonded to the substrate, and a pre-grind blade is used to remove portion of the wafer edge ring subject to poor bonding quality before grinding. The final thickness of the ground wafer is about 50 microns in either case.

### FIELD OF THE INVENTION

The present invention relates to a method for minimizing breakage of wafers during a wafer thinning process by trimming the beveled edge of the wafer prior to performing a wafer thinning process.

### BACKGROUND OF THE INVENTION

Current complementary metal-oxide-semiconductor (CMOS) or charge coupled device (CCD) image sensors have traditionally employed front-side illumination for image pickup. Front-side illumination has significant performance limitations, however, such as low fill factor/low sensitivity, and limited spectral response, because the device's metal circuitry structure, which is formed on the front surface of the chip in the pixel region, obscures a portion of the pixel area, resulting in a loss of photons reaching the active area of the pixel.

To solve these problems, especially for applications such as system-on-chip (SOC), four-transistor (4T) circuits, and for pixel sizes smaller than 1.7 micron×1.7 micron, back-side illuminated (BSI) image pickup has been proposed. BSI is advantageous because the photons are collected from the back side of the pixel area, and thus the active area of the pixels can be increased since there is no obstruction from the front side circuitry.

As part of the BSI manufacturing process, CMOS wafers are bonded to silicon or glass carrier substrates. Once this bonding process is completed, the wafer is thinned down to several microns using techniques such as grinding, polishing and/or etching. Wafers can be broken very easily during this “thinning” process (or during handling), thus degrading wafer yields and making the ultimate CMOS BSI manufacturing processes (including manufacturing micro-lenses and color filters) commercially impractical. The root cause of such breakage is believed to be the relatively poor bond that exists between the substrate and wafer near the wafer's outer edge, or perimeter. Because of this poor bonding at or near the edge, the wafer has insufficient support (from the carrier substrate) to resist forces due to grinding and handling, and thus the poorly bonded edge region can break.

In addition to the waste associated with wafer breakage, a large amount of particulate matter is generated when a wafer breaks. This particulate matter can damage the devices formed on other portions of the wafer, and if not effectively removed from the process stream, can damage subsequently processed non-broken wafers, such as by scratching, etc., thus further reducing production yields.

Thus, there is a need for a process that reduces or eliminates breakage of wafers that occurs during grinding, polishing or etching steps of the BSI production process. A desired process will be one that, through reduced breakage, improves overall yield in the production of BSI CMOS wafers, thus making the follow up micron-lens and color-filter processes commercially practical.

### SUMMARY OF THE INVENTION

A method for processing a semiconductor device, comprising: providing a semiconductor wafer having a front side and a back side, the front side having circuit elements disposed thereon, said wafer further having a thickness, and a periphery having a bevel region; trimming the wafer about the periphery to eliminate at least a portion of the bevel region; providing a carrier substrate; bonding the carrier substrate to the first major surface of the semiconductor wafer; and reducing the thickness of the wafer over at least a portion of the back side.

A method for processing a back-side illuminated CMOS device, comprising: providing a CMOS wafer having a front side and a back side, the front side having CMOS circuit elements disposed thereon, said CMOS wafer further having a thickness, and a periphery having a bevel region; providing a carrier substrate; bonding the carrier substrate to the first major surface of the semiconductor wafer; trimming the CMOS wafer about the periphery to eliminate at least a portion of the bevel region; and reducing the thickness of the wafer over at least a portion of the back side

A method for processing a back-side illuminated CMOS device, comprising: providing a CMOS wafer having first and second major surfaces, the first major surface comprising active circuitry elements; the CMOS wafer further having a thickness, and a bevel region disposed about a peripheral edge of the wafer; removing a first thickness of the CMOS wafer in the bevel region; and thinning the CMOS wafer by removing a second thickness of the wafer over at least a portion of the second major surface; wherein the second thickness is greater than the first thickness.

### BRIEF DESCRIPTION OF THE DRAWINGS

These and other features and advantages of the present invention will be more fully disclosed in, or rendered obvious by, the following detailed description of the preferred embodiment of the invention, which is to be considered together with the accompanying drawings wherein like numbers refer to like parts, and further wherein:

FIGS. 1A through 1D illustrate exemplary process steps for fabricating a typical CMOS BSI device;

FIGS. 2A and 2B are plan and partial cross-section views, respectively, of an exemplary semiconductor wafer;

FIG. 3 is a graph showing the edge profile of an exemplary semiconductor wafer;

FIGS. 4A through 4D show the process steps associated with the inventive wafer trimming process;

FIGS. 5A through 5C show the process steps associated with an alternative inventive wafer trimming process;

FIG. 6A is a plan view of an exemplary semiconductor wafer subsequent to backside thinning without pre-thinning edge trimming; FIG. 6B is a plan view of an exemplary semiconductor wafer subsequent to backside thinning with pre-thinning edge trimming.

### DETAILED DESCRIPTION

According to an embodiment of the present invention, disclosed herein is a method for reducing breakage of semiconductor wafers that presently occurs during the wafer thinning process associated with fabricating BSI CMOS devices. Specifically, a first example discloses trimming away a perimeter edge of the wafer prior to thinning the wafer. This trimming process may be implemented either before or after the wafer is bonded to a carrier substrate.

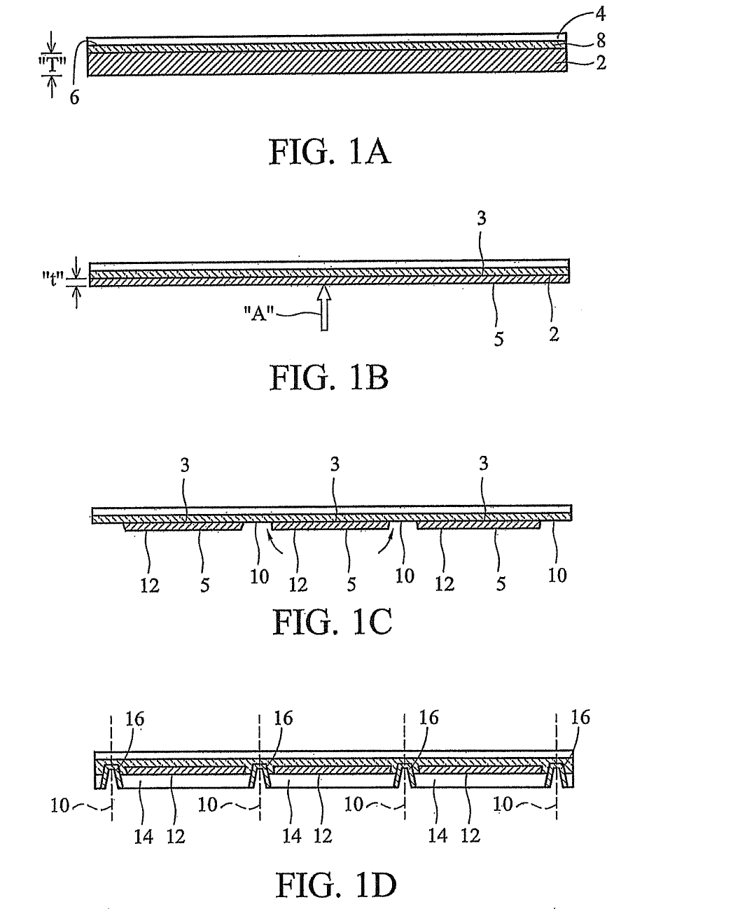

Referring to FIGS. 1A-D, an exemplary process for manufacturing a CMOS BSI imaging chip is shown. FIG. 1A shows a silicon wafer 2 bonded to a carrier substrate 4, which may be silicon, glass or other appropriate material. The wafer 2 may have a plurality of CMOS devices formed on one side, referred to as the “active surface” 6. In the illustrated embodiment, the carrier substrate 4 is bonded to the wafer 2 such that the active surface 6 facing up toward the substrate 4. The carrier substrate 4 may be coated by an adhesive layer 8, depending on the bonding method used. If so, the carrier substrate 4 may be bonded to the wafer 2 such that the side of the carrier substrate 4 containing the adhesive layer 8 faces the active surface 6 of the wafer 2.

The wafer 2 may have what are termed “front” 3 and “back” 5 sides. The front side 3 of the wafer 2 will typically comprise the active surface 6 (i.e., it will contain device wiring and other circuitry for the CMOS BSI device), while the back side 5 will function as the window through which photons will enter the pixel(s) of the imaging device. The wafer 2 may have an original thickness “T.” This original thickness may be too great to provide the desired degree of transparency for photon transmission to the pixel(s), and thus, the wafer 2 may be thinned (by grinding or other appropriate process) to achieve a reduced thickness “t”, as shown in FIG. 1B. At this reduced thickness “t” the wafer 2 may be sufficiently transparent that it allows a desired quantity of photons to hit the pixel(s). In one embodiment of the invention, the wafer 2 is ground to a thickness “t” of approximately 50 microns. In the present process, the wafer 2 will be ground from the back side 5 as shown by the arrow “A” in FIG. 1B.

After thinning, further processing of the wafer 2 then be performed, such as the addition of one or more encapsulating layers 14 and/or leads 16. The wafer 2 may then be etched along dice lines 10 as shown in FIG. 1C, and separated into individual dies 12 as shown in FIG. 1D.

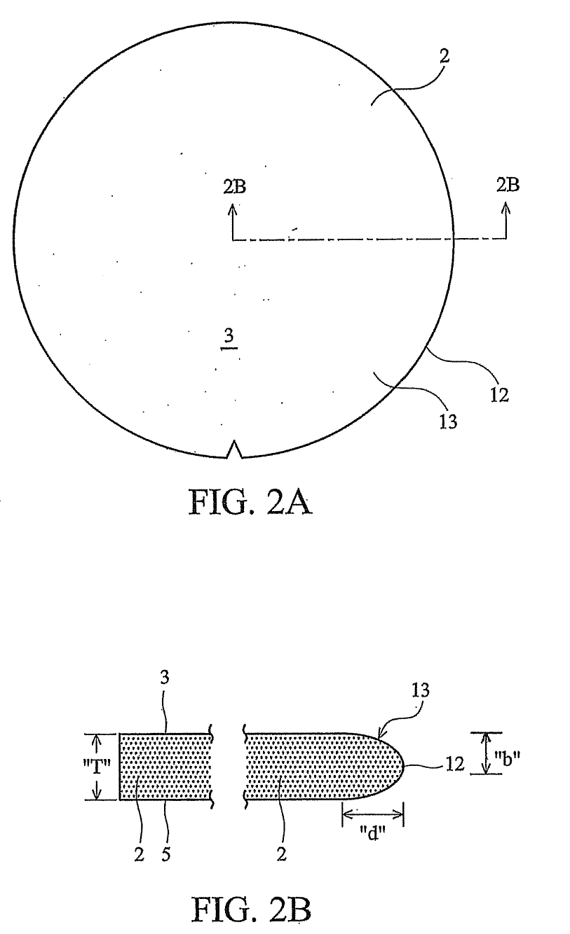

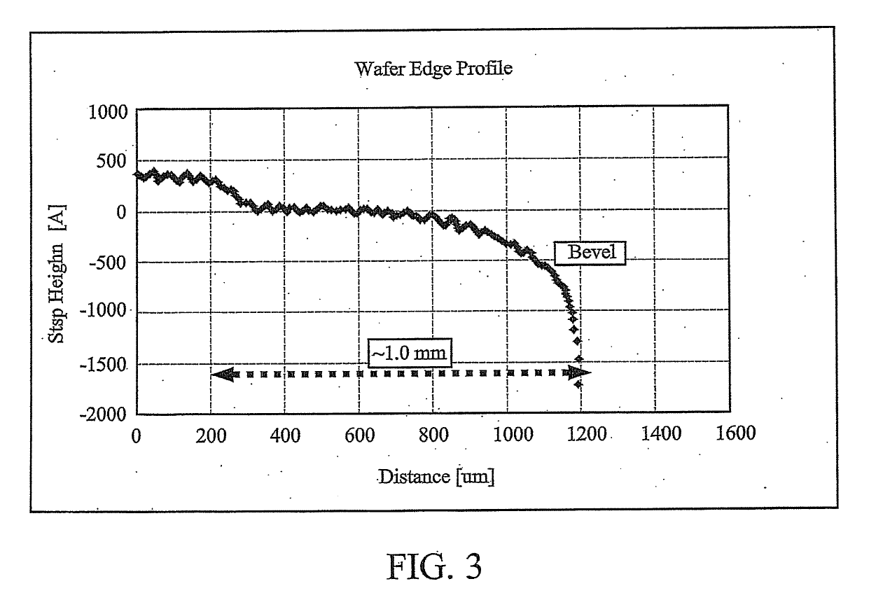

FIGS. 2A and 2B show wafer 2 with a front side 3, back side 5, thickness “T,” and perimeter 12. FIG. 2B shows the existence of a bevel region 13 located adjacent the perimeter 12 of the wafer 2. This bevel region 13 may exist around the entire perimeter 12 of the wafer 2, and is typically provided to prevent chipping or facilitate easy handling of the wafer 2. In one embodiment, this magnitude “b” of this bevel region 13 as measured at the perimeter 12 of the wafer is about 1500 Angstroms or larger, and it begins at a distance “d” of about 1.0 millimeters (mm) inward from the perimeter 12. A graphical illustration of the profile measurements of the bevel region 13 of an exemplary wafer 2 is provided in FIG. 3. It is in this bevel region 13, where bonding with the carrier substrate 4 is weakest, as will be described in greater detail below.

As previously noted, the wafer 2 may be bonded to a carrier substrate 4 (FIG. 1A). This carrier substrate 4 may provide, among other things, structural support for the wafer 2 while the wafer is being thinned, thus protecting the wafer from the substantial forces applied during physical grinding or polishing steps of the wafer thinning process. A variety of techniques may be used to bond the wafer 2 and carrier substrate 4, including some that require the use of an intermediate layer between the wafer 2 and carrier substrate 4, and some that do not.

One appropriate bonding technique is termed “direct bonding,” and is of the type that does not require an intermediate layer between the wafer 2 and carrier substrate 4. The direct bonding process involves pressing the wafer and substrate together and heating the combination to about 1000 degrees Celsius (° C.) for a predetermined time period. Alternative direct bonding techniques include “surface activated bonding,” and “vacuum bonding.” With surface activated bonding, the surfaces of the wafer and carrier substrate are made atomically clean by argon fast atom beam (Ar-FEB) in ultra high vacuum (UHV) and brought into contact. This may be performed at room temperature, or at elevated temperatures of about 200-250° C. With vacuum bonding, the wafer and carrier substrate are pressed together using a vacuum, and heated to about 200-250° C.

Alternatively, “anodic bonding,” techniques may be used, in which the wafer 2 and carrier substrate 4 are clamped together between two metal electrodes, heated to about 300-500° C., and a potential difference of about 1000 Volts is applied between the two. Where a glass carrier substrate 4 is used, sodium ions are displaced from the bonding surface of the glass by the applied electric field. The depletion of sodium ions near the surface of the glass makes the surface highly reactive with the silicon surface of the wafer, thus forming a solid chemical bond between the two.

Examples of bonding techniques that require an intermediate layer include eutectic bonding, adhesive bonding, and glass frit bonding. Eutectic bonding involves coating the wafer 2 and carrier substrate 4 with separate components of a eutectic alloy composition. The two wafers are then heated and brought into contact, and diffusion occurs at the interface and alloys are formed. It is the melted eutectic layer that forms the bond. In one exemplary embodiment, a Si—Au eutectic alloy is used, and the process is performed at about 370° C.

Adhesive bonding, using epoxies, silicones, photoresists, polyimides, etc., can also be used to bond the wafer and carrier substrate. Typically, adhesive bonding requires the application of heat (about 120-140° C.).

Glass Frit bonding is a further alternative technique for bonding the wafer and carrier substrate, and involves the use of a low melting point glass material to form the bond between the pieces. The glass layer may be applied to one or both pieces as a preform, spin-on, screen print, sputtered film, etc. and may be patterned to define sealing areas. The wafer and carrier substrate are then pressed together and heated to about 400-500° C.

Although all of these processes have been used successfully to achieve bonding between wafers and carrier substrates, their effectiveness is limited to the flat regions of those pieces, and still the problem of poor bonding between the pieces at the bevel region 13 remains.

As previously noted, breakage/cracking of the wafer 2 in the bevel region 13 quickly propagates into the device areas of the wafer 2, resulting in the aforementioned waste. Since it may not be practical to achieve complete bonding of the wafer and carrier substrate in the bevel region, a solution to the breakage problem is to remove the offending portion of the bevel region. By eliminating the inception point of the breakage (the bevel region, or region of inadequate bonding) prior to the thinning process, wafer breakage may be effectively reduced or eliminated.

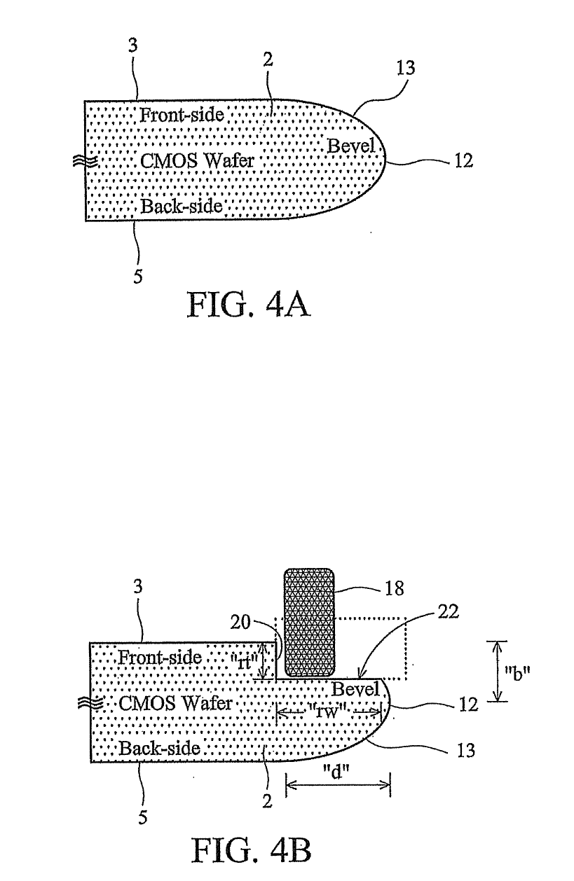

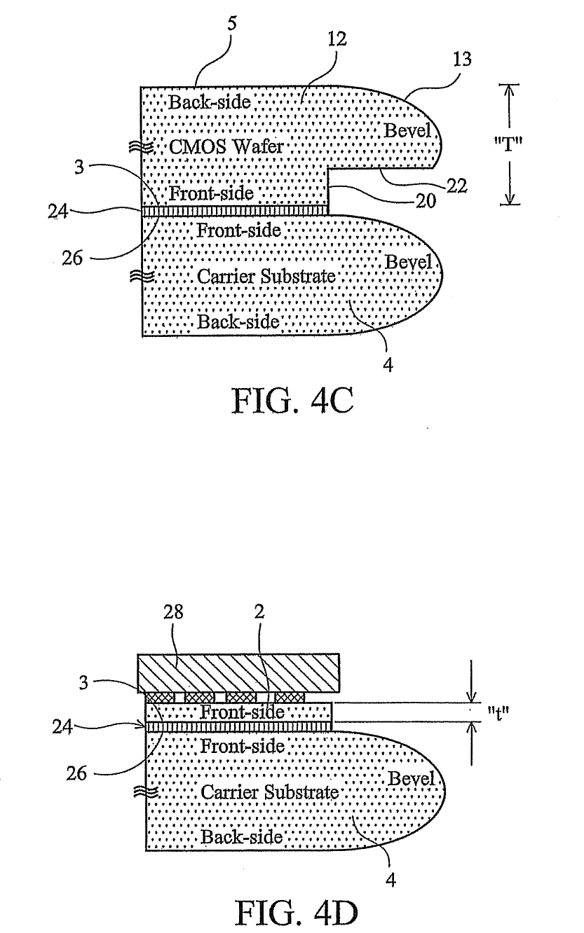

Referring to FIGS. 4A-4D, one exemplary embodiment of a fabrication process incorporating such edge trimming (i.e., removal of the bevel region) is shown. FIG. 4A is a partial cross-section view of the wafer 2 having a front side 3, back side 5, and bevel region 13. FIG. 4B shows the use of a cutting blade 18 to remove a portion of the bevel region 13 adjacent the front side 3 of the wafer 2. As can be seen, the cutting blade 18 may be positioned so that it removes a thickness “rt” and a band width “rw” of the wafer 2, and creates substantially flat side and bottom walls 20, 22 in the wafer 2 about the perimeter 12. In the illustrated embodiment, the blade 18 is positioned to remove a thickness “rt” of the wafer 2 that is smaller than the magnitude “b” of the bevel region 13. The cutting blade 18 also is positioned to remove a band width “rw” of the wafer 2 that at least reaches the distance “d” at which the bevel region 13 extends inward from the perimeter 12 of the wafer 2.

The trimming can proceed can be performed by making a single pass of the cutting blade 18 around the wafer perimeter 12, or by maintaining the cutting blade stationary and rotating the wafer 2. Alternatively, multiple cutting passes may be made, to obtain the desired reduced band width dimension “rw”. Multiple cutting passes may be appropriate when a larger band width dimension “rw” is desired. Additionally, when multiple cutting passes are employed, the cutting blade may be moved in a spiral fashion with respect to the wafer, or it may be moved in an oscillating fashion. In one embodiment, this band width dimension “rw” is from about 0.3 mm to about 5.0 mm, and preferably about 2.0 mm. Thus, in one embodiment, the band width dimension “rw” is about 2.0 mm, and the trimming depth is selected to provide a desired final thickness of about 25 μm to about 50 μm.

Once the blade 18 has been used to remove an appropriate portion of the bevel region 13, the wafer 2 may be bonded to the carrier substrate 4 as illustrated in FIG. 4C using one of the bonding techniques previously described. FIG. 4C shows the use of an intermediate layer 24 to bond a front side 26 of the carrier substrate 4 to the front side 3 of the wafer 2. This intermediate layer 24 is optional, depending on the type of bonding technique used. As can be seen, the flat front side 3 of the wafer 3 is fully bonded with the front side 26 of the carrier substrate 4.

FIG. 4D shows the wafer thinning step, in which a grinding wheel 28 is used to grind the wafer 2, from the back side 5, until a desired wafer thickness “t” is achieved. As previously noted, other thinning techniques, such as polishing or etching can be used in place of a grinding wheel. Additionally, combinations of such processes can also be implemented.

In an alternative to the edge trimming step shown in FIG. 4B (in which only a portion of the bevel region 13 is removed) the entire bevel portion 13 may be removed prior to bonding, thus providing a completely flat perimeter 12 profile.

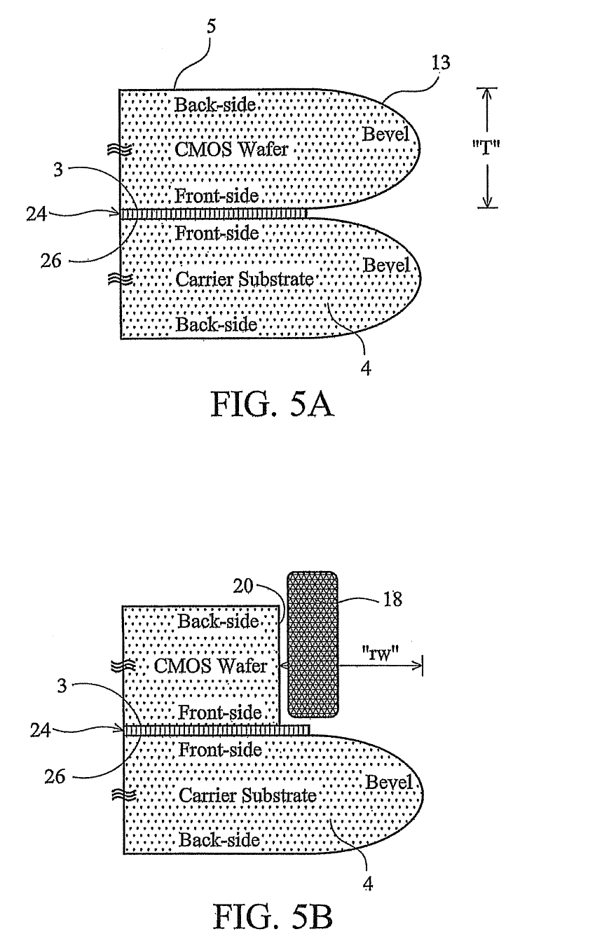

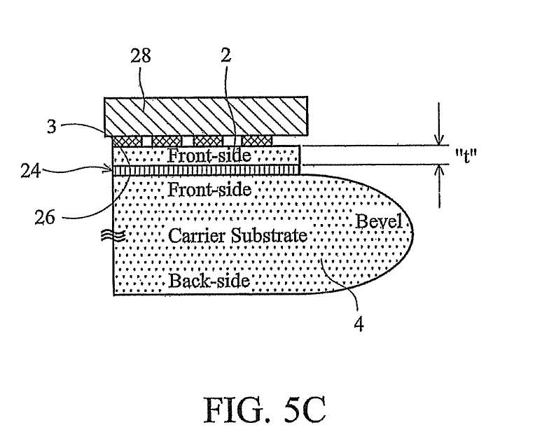

An alternative fabrication process incorporating edge trimming is shown in FIGS. 5A-C. FIG. 5A is a partial cross-section view of the wafer 2 having a front side 3, back side 5, and bevel region 13. In this method, the wafer 2 and carrier substrate 4 are bonded together using one of the aforementioned bonding techniques, so that the front side 3 of the wafer 2 faces a front side of the carrier substrate 4. The wafer 2 and carrier substrate 4 are bonded using an intermediate layer 24. Again, this layer is optional, depending on the bonding technique used.

FIG. 5B shows the use of a cutting blade 18 to remove the entire bevel region 13 of the wafer 2 so that a flat side wall 20 is formed about the entire periphery of the wafer 2. As can be seen, the cutting blade 18 may be positioned so that it removes a width “rw” of the wafer 2 sufficient to remove the entire bevel region 13, leaving only the substantially flat portions of the front and back sides 3, 5 of the wafer. This post-bond trimming step eliminates the region of the wafer 2 that is subject to poor bonding with the carrier substrate 4.

Once the bevel region 13 of the wafer 2 has been removed, the wafer 2 may be thinned as shown in FIG. 5C to provide a finished wafer thickness “t,” which may be from about 1 μm to about 100 μm, and more preferably from about 10 μm to about 100 μm. The thinning process may be substantially the same as that described above in relation to FIG. 4D.

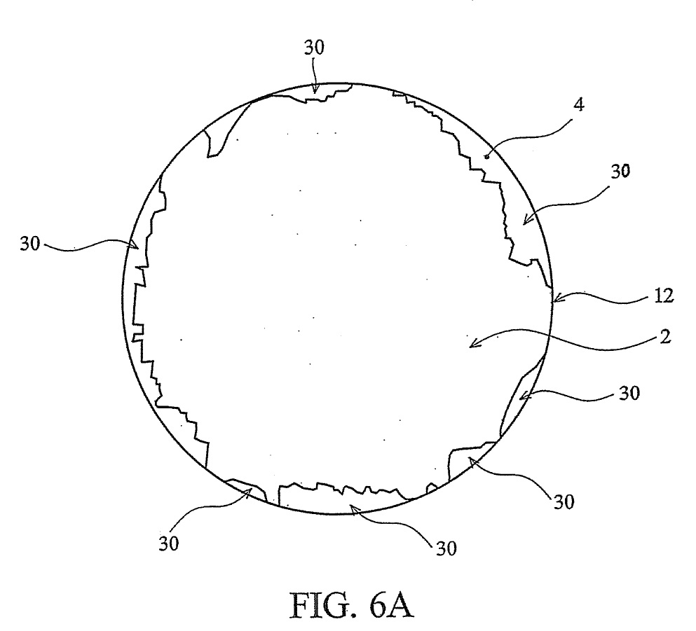

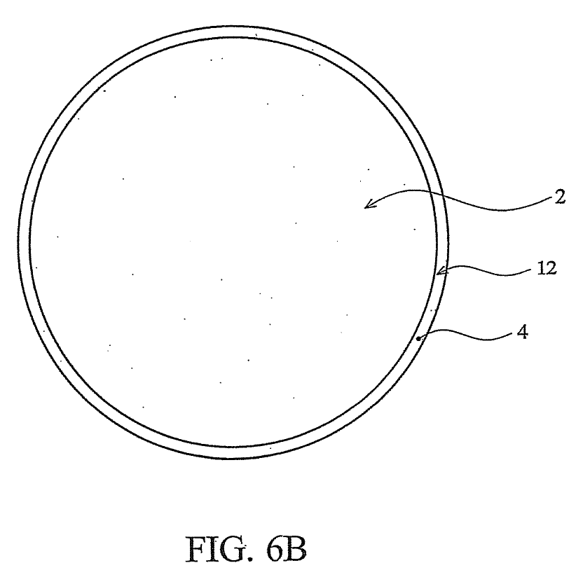

Referring to FIGS. 6A and 6B, a pair of wafers 2 are shown. The wafer 2 of FIG. 6A was thinned using a traditional process in which the wafer 2 is bonded to the carrier substrate 4 and then thinned by grinding the back side 5 of the wafer. As can be seen, numerous chipped and broken regions 30 exist about the perimeter 12 of the wafer 2. The wafer 2 of FIG. 6B, was prepared according to the inventive process in which at least a portion of the bevel region 13 of the wafer 2 was removed prior to thinning. As can be seen, there are no chipped or broken regions of the wafer 2 of FIG. 6B.

As an alternative to the blade trimming technique described above, a wet etching process could be used to remove all or a portion of the bevel region 13 as part of the process steps of FIGS. 4A-5C. Additionally, edge bead remover could be used to remove wafer bevel/edge thickness.

Although wafer cracking could be reduced by providing a carrier substrate 4 having a diameter that is substantially larger than that of the wafer 2, such a process would require modification of the wafer handling tool, among other tools. Thus, edge trimming is viewed as a simpler way of avoiding wafer breakage.

Additionally, although the wafer edge trimming process has been described in relation to the BSI manufacturing process, it may also be used in MEMS or SOI processes which implement wafer bonding and backside grinding steps.

While the foregoing invention has been described with reference to the above embodiments, various modifications and changes can be made without departing from the spirit of the invention. Accordingly, all such modifications and changes are considered to be within the scope and range of equivalents of the appended claims.

1. A method for processing a semiconductor device, comprising:
providing a semiconductor wafer having a front side and a back side, the front side having circuit elements disposed thereon, the wafer further having a thickness, and a periphery having a bevel region;
trimming the wafer about the periphery to eliminate at least a portion of the bevel region;
providing a carrier substrate;
bonding the carrier substrate to the first major surface of the semiconductor wafer; and
reducing(thinning) the thickness of the wafer over at least a portion of the back side.

2. The method of claim 1, wherein the trimming step reduces the thickness of the wafer in an annular ring around the periphery of the wafer.

3. The method of claim 2, wherein the reducing step reduces the wafer thickness to about 50 microns or less for wafers having a diamater of less than about 8 inches.

4. The method of claim 2, wherein the reducing step reduces the wafer thickness to about 100 microns or less for wafers having a diameter of about 12 inches.

5. The method of claim 1, wherein the bonding step comprises using an intermediate bonding material disposed between the wafer and the carrier substrate.

6. The method of claim 1, wherein the trimming step is performed using multiple trimming passes with a trimming blade to remove wafer material in increments.

7. The method of claim 6, wherein the trimming process comprises one or more fabrication processes selected from the group consisting of: mechanical trimming, chemical trimming, and laser cutting.

8. The method of claim 7, wherein the trimming step removes a ring of wafer material from around the perimeter of the wafer, the ring having a dimension of about 2 mm.

9. The method of claim 1, wherein the carrier substrate comprises glass or silicon material.

10. A method for processing a back-side illuminated CMOS device, comprising:
providing a CMOS wafer having a front side and a back side, the front side having CMOS circuit elements disposed thereon, said CMOS wafer further having a thickness, and a periphery having a bevel region;
providing a carrier substrate;
bonding the carrier substrate to the first major surface of the CMOS wafer;
trimming the CMOS wafer about the periphery to eliminate at least a portion of the bevel region; and
thinning the thickness of the wafer over at least a portion of the back side.

11. The method of claim 10, wherein the trimming step reduces the thickness of the wafer in an annular ring around the periphery of the wafer.

12. The method of claim 11, wherein the thinning step reduces the wafer thickness to about 50 microns or less for wafers having a diameter of less than about 8 inches.

13. The method of claim 12, wherein the trimming step reduces the wafer thickness to about 100 microns or less for wafers having a diameter of about 12 inches.

14. The method of claim 10, wherein the bonding step comprises using an intermediate bonding material disposed between the wafer and the carrier substrate.

15. The method of claim 10, wherein the trimming step is performed using multiple trimming passes with a trimming blade to remove wafer material in increments.

16. The method of claim 15, wherein the trimming process comprises one or more fabrication processes selected from the group consisting of: mechanical trimming, chemical trimming, and laser cutting

17. The method of claim 15, wherein the trimming step removes a ring of wafer material from around the perimeter of the wafer, the ring having a dimension of about 2 mm.

18. The method of claim 10, wherein the carrier substrate comprises glass or silicon material.

19. A method for processing a back-side illuminated CMOS device, comprising:
providing a CMOS wafer having first and second major surfaces, the first major surface comprising active circuitry elements; the CMOS wafer further having a thickness, and a bevel region disposed about a peripheral edge of the wafer;
removing a first thickness of the CMOS wafer in the bevel region; and
thinning the CMOS wafer by removing a second thickness of the wafer over at least a portion of the second major surface;
wherein the second thickness is greater than the first thickness.

20. The method of claim 19, further comprising:
providing a carrier substrate; and
bonding the carrier substrate to the first major surface of the wafer;
wherein the removing step occurs prior to the bonding step.

21. The method of claim 19, further comprising:
providing a carrier substrate; and
bonding the carrier substrate to the first major surface of the wafer;
wherein the removing step occurs after the bonding step.

22. The method of claim 19, wherein the removing step reduces the thickness of the wafer in an annular ring around the periphery of the wafer.

23. The method of claim 19, wherein the removing step is performed using multiple trimming passes with a trimming blade to remove wafer material in increments.

24. The method of claim 19, wherein the removing step removes a ring of wafer material from around the perimeter of the wafer, the ring having a dimension of about 1.5 mm.
